(19) United States
(12) Patent Application Publication
(10) Pub. No.: US 2013/0341294 A1
(43) Pub. Date: Dec. 26, 2013

(54) BRAKE SYSTEM AND METHOD FOR A ROTATING FRAME IN A SOLAR POWER GENERATION SYSTEM

(71) Applicant: GOSSAMER SPACE FRAMES, (US)

(72) Inventors: Glenn A. Reynolds, Laguna Hills, CA (US); Dean Robert Hackbarth, Las Vegas, NV (US); Gary Noble Curtis, Anacortes, WA (US)

(73) Assignee: GOSSAMER SPACE FRAMES, Huntington Beach, CA (US)

(21) Appl. No.: 13/875,842

(22) Filed: May 2, 2013

Related U.S. Application Data
(60) Provisional application No. 61/641,801, filed on May 2, 2012.

(51) Int. Cl. H01L 31/042

(52) U.S. Cl. CPC H01L 31/0422
USPC 211/26; 248/351; 29/592

(57) ABSTRACT

A brake system for a frame of a solar power generation system, where the frame is rotatable relative to a frame support to track the position of the sun includes a ramp having a first end coupled to the frame support and a second end coupled to the ground and a brake arm assembly. The brake arm assembly is rotationally coupled to the frame and configured to moveably engage the ramp from an operative position of the frame wherein the frame is rotatable about the support in a rotational direction to a parked position of the frame wherein the brake arm assembly couples to the frame support to prevent the frame from rotating about the frame support in the rotational direction.

### RELATED APPLICATION

The present application claims the benefit of the filing date of U.S. Provisional Application Ser. No. 61/641,801, filed May 2, 2012, the entire disclosure of which is incorporated by reference herein.

### FIELD

This disclosure generally relates to solar power generation systems, and more particularly, to a brake system and method for a rotating frame in a solar power generation system.

### BACKGROUND

Reflective solar power generation systems may either use a number of spaced apart reflective panels that surround a central tower and reflect sunlight toward the central tower or parabolic-shaped reflective panels that focus sunlight onto a tube at the focal point of the parabola defining the reflective panels. The latter system may be referred to as a solar trough system. During high winds, severe storms and or periods when the solar trough system is inoperative or stowed, such as at night, a brake system may be necessary to generally secure each frame that defines a trough to prevent any possible damage to the frame structure.

### BRIEF DESCRIPTION OF THE DRAWINGS

FIG. 1 shows a reflector frame assembly according to one exemplary embodiment.

FIG. 2 shows a side view of the reflector frame assembly of FIG. 1.

FIGS. 3 and 4 show side and perspective views, respectively, of a brake ramp of a brake system according to one embodiment.

FIG. 5 shows a perspective view of a brake arm of a brake system according to one embodiment.

FIGS. 6-26 are front, side and perspective views of a brake system according to one embodiment showing operation of the braking system.

FIGS. 27 and 28 show a brake system according to another embodiment.

### DETAILED DESCRIPTION

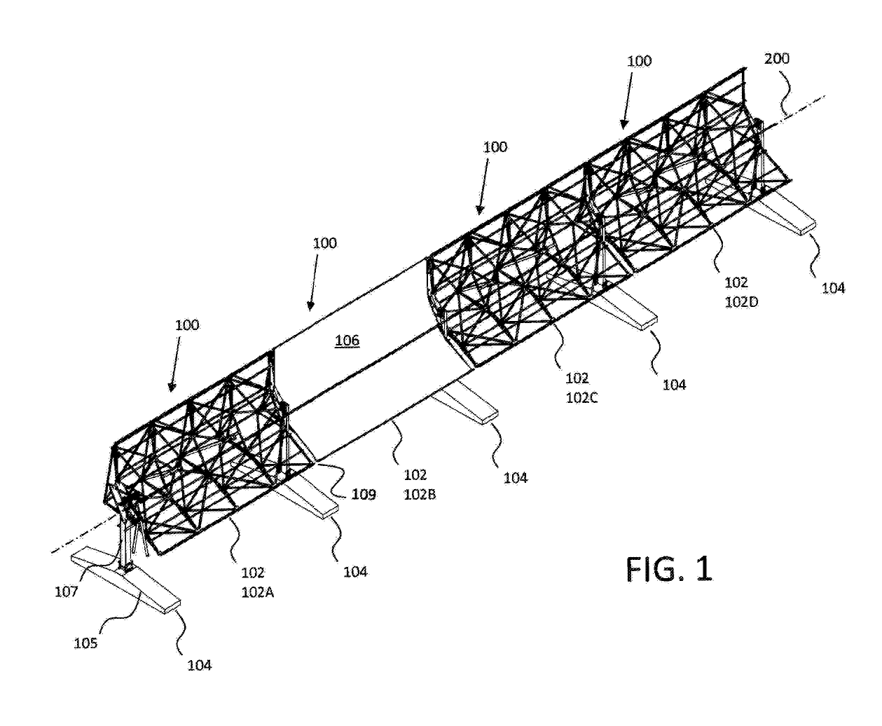

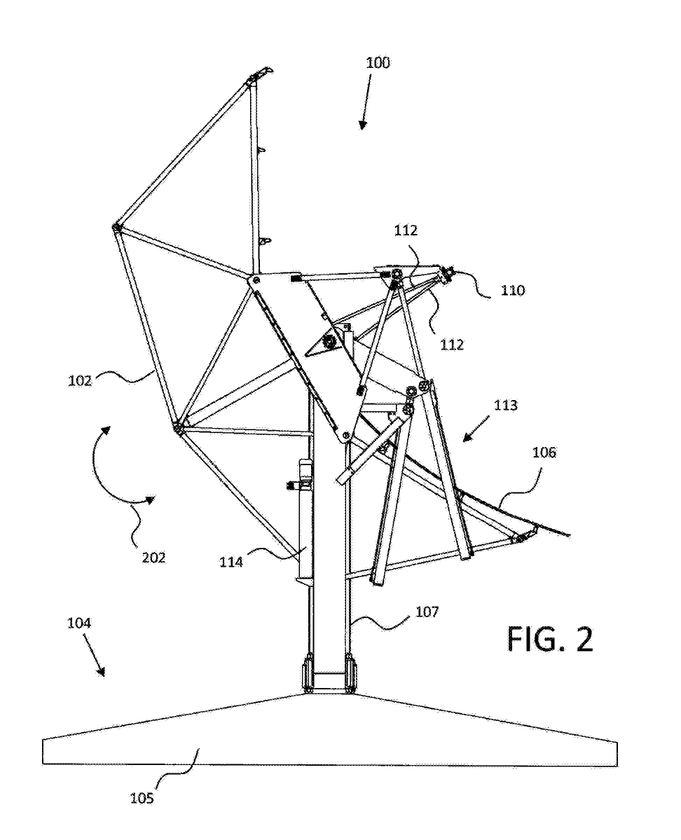

Referring to FIG. 1, a plurality of reflector frame assemblies 100 forming a section of a solar power generation system is shown. Each reflector frame assembly 100 includes a frame 102, which is rotatably mounted on one or more support pylons 104, and can rotate about a center axis or rotation axis 200 to track the daily east to west movement of the sun. Each support pylon may include a base 105 and a support beam 107. Referring also to FIG. 2, each frame 102 has a concave or trough-shaped side, to which one or more reflectors 106 (only one reflector is shown in FIG. 1) are connected. The reflectors 106 may be constructed from any type of rigid (e.g., glass) or flexible material (e.g., reflective film) that provides a reflective surface. The reflectors 106 may be constructed from a flexible reflective material that is mounted to a backing structure. The reflectors 106 can be connected to the frame by any device and/or method.

Referring to FIG. 2, the reflectors 106 reflect and focus sunlight onto a tube 110, which may extend generally along a focal line of one or more frames 102. Multiple frames 102 may be connected to each other at each support beam 107 such that a frame gap 109 is present between each frame 102. The width of the frame gap 105 is greater than the width of each support beam 107 so that the support beams 107 can traverse through the corresponding frame gaps 109 during rotation of the frames 102 (see for example, FIG. 23). In the example of FIG. 1, the tube 110 is shown to extend generally along a focal line of four frames 102A-102D. The tube 110 may be mounted with tube mounts 112 to each frame 102. When the reflectors 106 are directly facing the sun, the reflectors 106 reflect the sunlight generally onto the tube 110. The tube 110 serves as a conduit for carrying a heat transfer fluid (HTF) that can transfer the heat generated by the focused sunlight to a power generation section (not shown) of the solar power generation system. Each reflector frame assembly 100 may include a drive mechanism 113 and controller 114, which may be collectively referred to herein as a control system 115. Each frame 102 is rotated about the axis 200 (shown in FIG. 1) by the control system 115 to track the daily movement of the sun. The direction of rotation is shown by the arrow 202 in FIG. 2. The control system 114 may provide continuous tracking of the sun, thereby providing continuous focusing of sunlight onto the tube 110. Any type of analog and/or digital control system utilizing classical and/or modern control techniques may be used to provide continuous and or discrete solar tracking of the reflector frames 102.

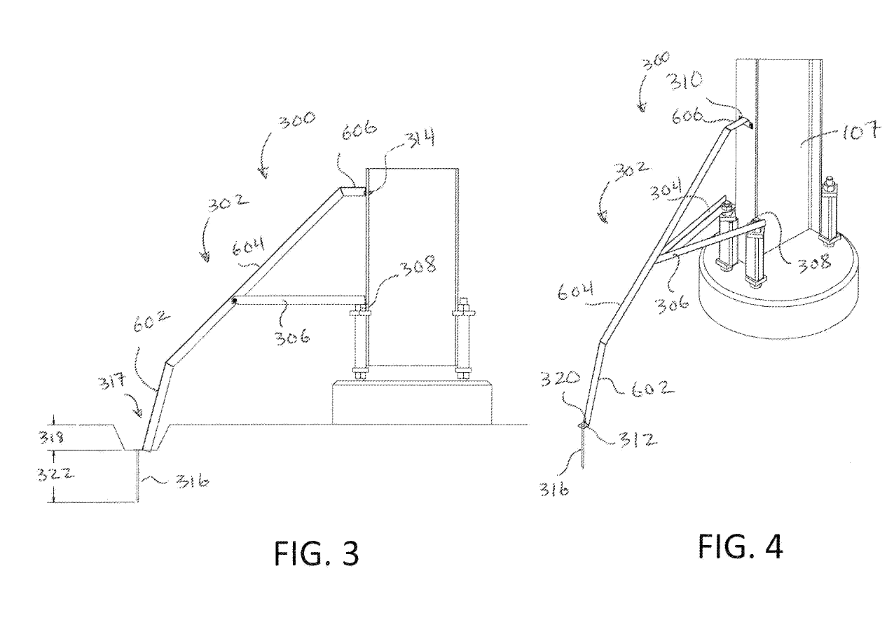

Referring to FIGS. 3 and 4, a brake ramp assembly 300 of a brake system according to one embodiment is shown. The brake ramp assembly 300 includes a brake ramp 302 that may be attached to the support beam 107. The brake ramp 302 may be attached to the support beam 107 by any type of fastener, welding, or any other system and method which can securely attach the brake ramp 302 to the support beam 107. The brake ramp 302 may be directly attached to the support team 107 or indirectly attached to the support beam 107 through one or more connection members (not shown). In the example of FIG. 4, the brake ramp assembly 300 includes a first brace 304 and a second brace 306, which attach the brake ramp 302 to the support beam 107 at two locations with bolts 308. The first brace 304 and the second brace 306 may support a portion of the brake ramp 302 between the first end 310 and the second end 312 of the brake ramp 302. The first end 310 of the brake ramp 302 may be attached to the support beam 107 with any type of fastener such as the bolt 314, or by welding. The second end 312 of the brake ramp 302 may be secured to the ground with a stake or nail 316. As shown in FIG. 3, a hole 317 having a depth 318 may be provided for grounding the second end 312 of the brake ramp 302. The second end 312 may be placed in the hole 317 as shown in FIG. 3, and the nail 316 may then be inserted in a hole (not shown) of a flange portion 320 at the second and 312 and into the ground at a depth 322 which may be generally equal to the length of the nail 316. The hole 317 may then be backfilled with dirt or concrete or other materials. Accordingly, the brake ramp 302 may be secured at three points, which are the first end 310, the second end 312, and the location between the first end 310 and the second end 312 as defined by the first brace 304 and the second brace 306.

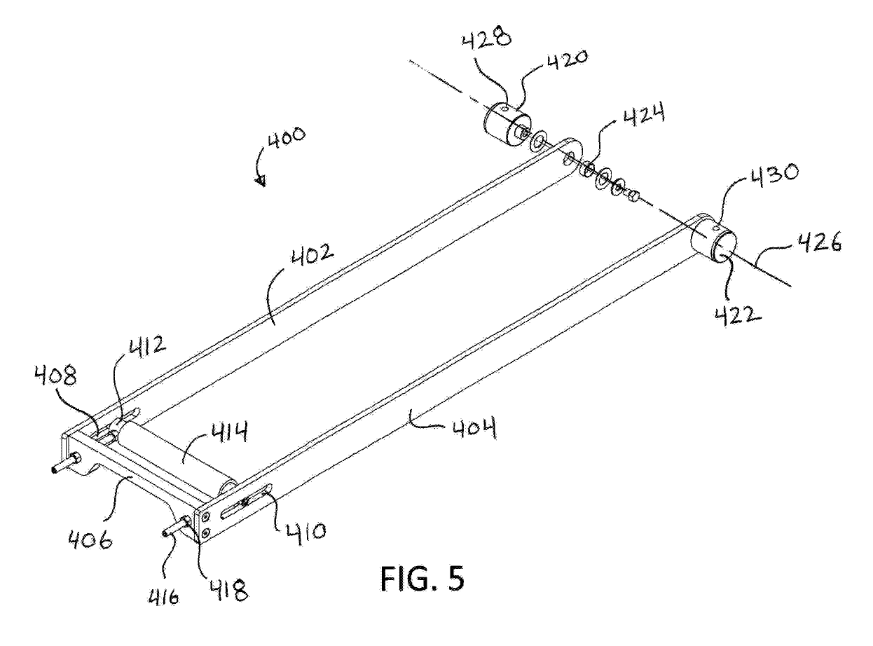

Referring to FIG. 5, a brake arm assembly 400 according to one embodiment is shown. The brake arm assembly 400 includes a first brake arm 402 and a second brake arm 404 that are attached but are spaced apart by a crossbar 406. The first brake arm 402 includes an adjustment slot 408 near the crossbar 406 and the second brake arm 404 includes an adjustment slot 410 near the crossbar 406 and opposite to the adjustment slot 408. The adjustment slots 408 and 410 slidably receive a roller bar 412. A roller sleeve 414 is rotatably mounted on the roller bar 412 and can rotate about the longitudinal axis of the roller bar 412. The roller sleeve 414 may be rotationally mounted on the roller bar 412 with one or more bearings (not shown). The roller bar 412 is movable in the adjustment slots 408 and 410 so that the distance of the roller bar 412 can be adjusted relative to the crossbar 406. The position of the roller bar 412 in the slots 408 and 410 may be fixed with adjustment screws 416 and corresponding adjustment nuts 418 positioned near the opposite ends of the roller bar 412.

The first brake arm 402 and the second brake arm 404 include a first attachment pin 420 and a second attachment pin 422 at the ends of the first brake arm 402 and the second brake arm 404 opposite to the crossbar 406, respectively. Each attachment pin 420 and 422 is rotationally mounted to the corresponding first brake arm 402 and the second brake arm 404 with a corresponding bearing. In FIG. 5, only one bearing 424 is shown for the attachment pin 420. Accordingly, the first brake arm 402 and the second brake arm 404 rotate relative to the attachment pins 420 and 422. Referring to FIG. 8, each attachment pin 420 and 422 is mounted in a passage of a node connector 500 and 502 of a frame 102, respectively. Each attachment pin 420 and 422 includes a pinhole 428 and 430, respectively, for receiving a locking pin (not shown). The passage of each of the node connectors 500 and 502 also includes a pinhole (not shown) for receiving the locking pin. Insertion of the locking pin in the corresponding pinholes attaches a corresponding attachment pin 500 and 502 to the corresponding frame 102. The attachment pin may have any cross-sectional shape such as cylindrical, square or oval. Accordingly, the passage of each node connector 500 and 502 may have a corresponding cross-sectional shape. Details of connecting the attachment pins 420 and 422 to the node connectors 500 and 502 with locking pins is provided in U.S. Pat. No. 7,578,109, the disclosure of which is incorporated by reference herein. Thus, the brake arm assembly 400 can rotates about the ads 426 relative to the node connectors 500 and 502 or relative to the frames 102 corresponding to the node connectors 500 and 502.

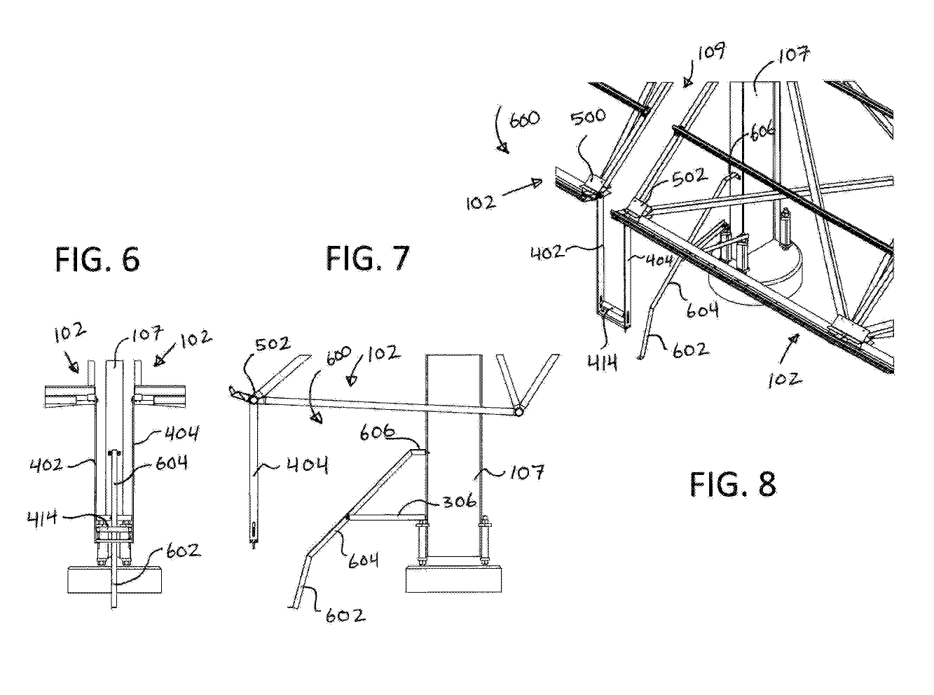

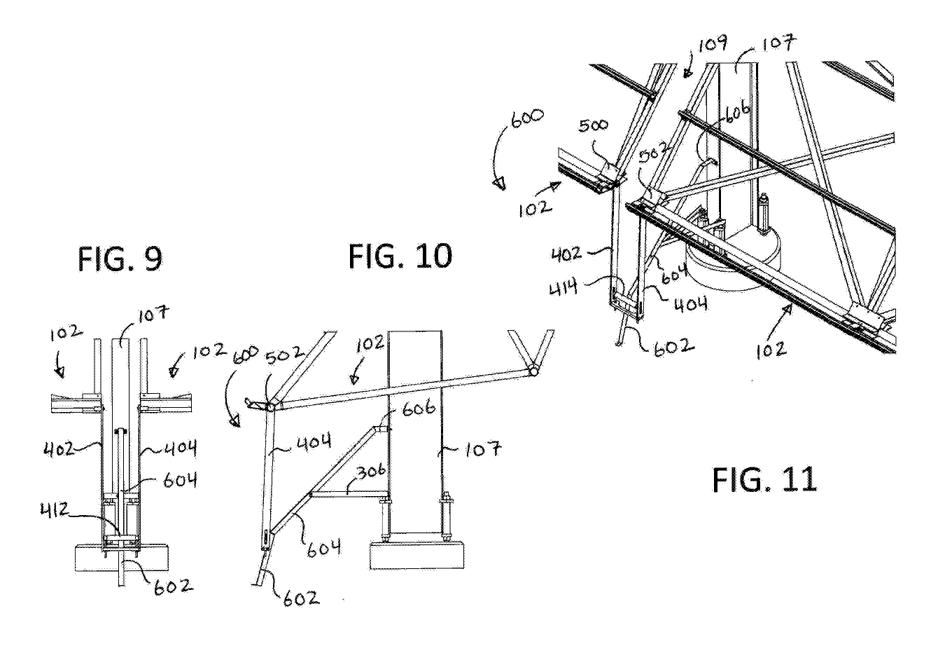

Referring to FIGS. 6-8, each frame 102 rotates about a center axis or rotation axis 200 (shown in FIG. 1) to track the daily east to west movement of the sun. During the daily operational position of each frame 102, which may be referred to herein as the operative position of the frame 102, the brake arm assembly 400 maintains a vertical orientation as shown in FIGS. 7 and 8, because the brake arm assembly 400 is freely rotatable relative to the frames 102. Thus, the brake arm assembly 400 does not interfere with the daily operation of the frames 102. During periods of high wind and/or storms, the frames 102 may be rotated to a parked position and secured in the parked position so as to prevent damage to the frames, the reflectors, the pylons, and any other component of the reflector frame assembly 100. Furthermore, during inoperative periods of the reflector frame assembly 100 such as after each daily operation, the frames 102 may be parked and secured in the parked position to prevent any possible damage during the night as a result of high winds and/or storms.

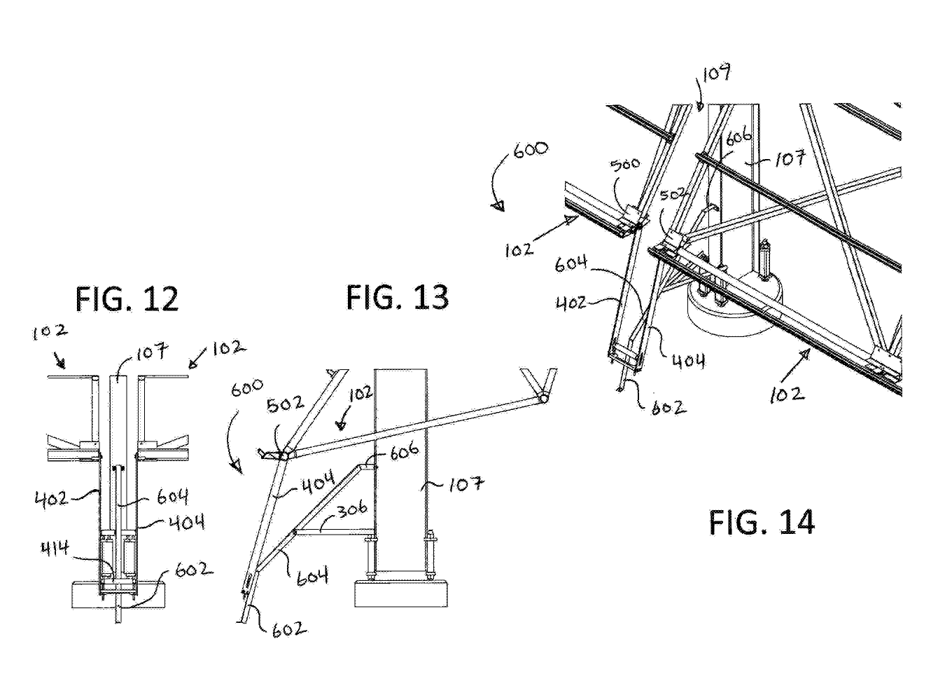

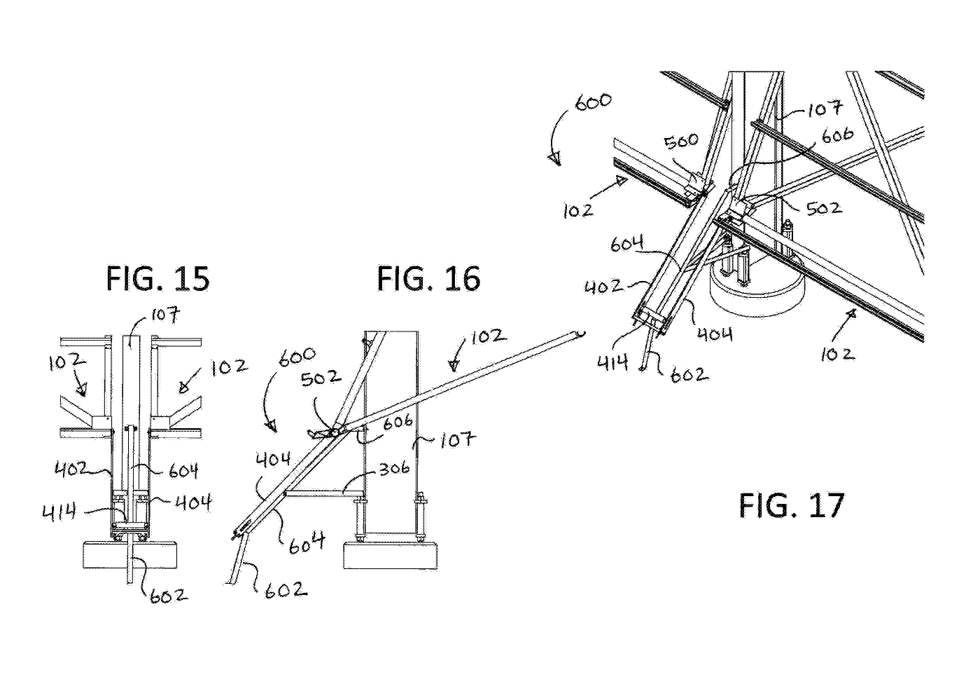

To place the frames 102 in a parked position, the frames 102 are rotated in a direction 600 shown in FIGS. 10 and 11. As shown in FIG. 11, as the frames 102 are rotated in the direction 600, the roller sleeve 414 reaches and contacts a first segment 602 of the brake ramp 302. Referring to FIGS. 12-17, as the frames 102 are further rotated in the direction 600, the roller sleeve 414 rolls on the first segment 602 of the brake ramp 302 to transition on to a second segment 604 of the brake ramp 302. As the roller sleeve 414 rolls on the first segment 602 and the second segment 604 as a result of the frames 102 rotating in the direction 600, the entire brake arm assembly 400 rotates about the axis 426 (shown in FIG. 5) so that the roller sleeve 414 remains continuously engaged to the brake ramp 302. Additionally, as shown for example in FIGS. 19 and 20, the support beam 107 passes through the gap 109 between the frames 102.

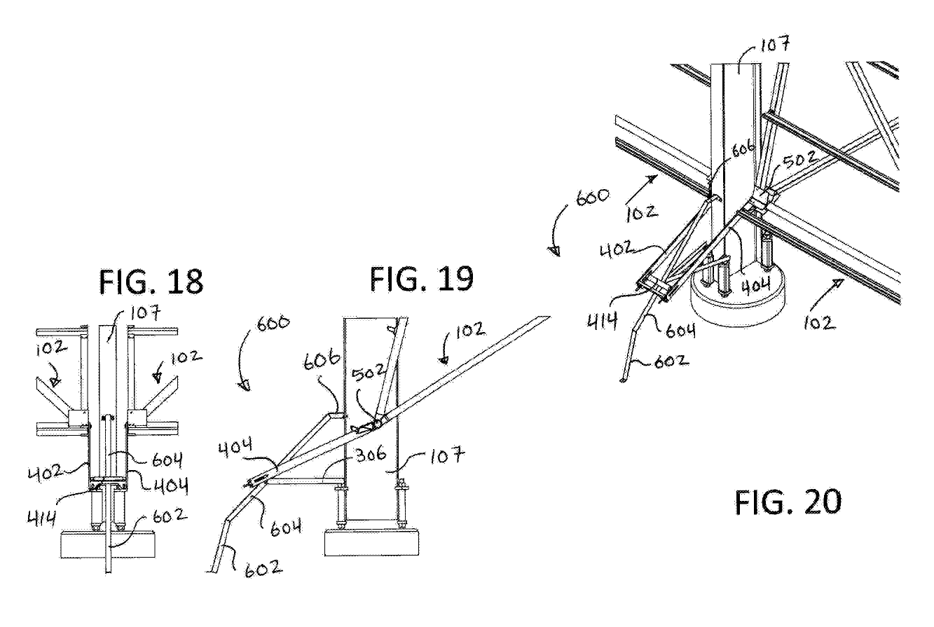

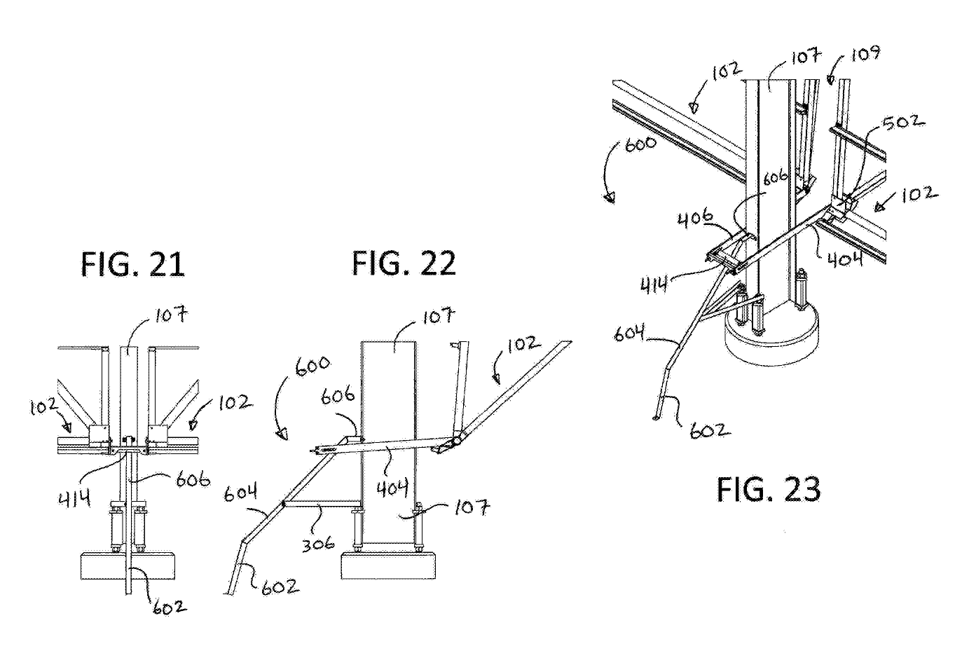

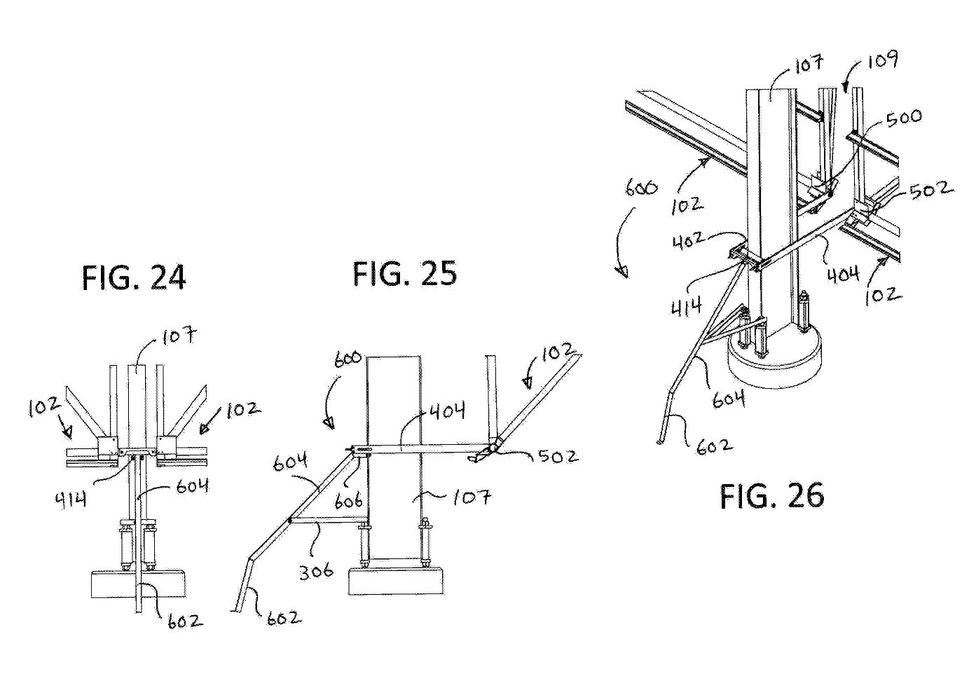

Referring to FIGS. 18-23 as the frames 102 are further rotated in the direction 600, the roller sleeve 414 remains engaged on the second segment 604 and rolls on the second segment 604 thereby further rotating the entire brake arm assembly 400 about the axis 426. Referring to FIGS. 24-26, the roller sleeve 414 then transitions onto a third segment 606 of the brake ramp 302, which may be a generally horizontal segment. As shown in FIG. 26, further rotation of the frames 102 causes the roller sleeve 414 to engage the support beam 107 and stop any further rotation of the frame 102 in the direction 600. The position of the frames 102 shown in FIGS. 25 and 26 represent the parked position of the frames 102. Any further rotation of the frames 102 from the park position in the direction 600 is prevented by the engagement of the roller sleeve 414 with the support beam 107.

Referring back to FIG. 5, the support beams 107 of a reflector frame assembly 100 may not be perfectly aligned. Accordingly, when the frames 102 are moved into the parked position, the roller sleeves 414 of one or more brake arm assemblies 400 may engage the corresponding support beams 107, while the roller sleeves of one or more brake arm assemblies 400 may not engage the corresponding support beams 107. In order to ensure that all roller sleeves 414 of all brake arm assemblies 400 in a reflector frame assembly 100 engage the corresponding support beams 107 in the parked position of the frames 102, the location of the roller bar 412 in the adjustment slots 408 and 410 can be adjusted as needed. For each brake arm assembly 400, the adjustment nuts 418 on the adjustment screws 416 can be loosened. The roller bar 412 may then be shifted in the adjustment slots 408 and 410 until a preferred position of the roller sleeve 414 is achieved such that the roller sleeve 414 engages the corresponding support beam 107 in the parked position of the frames 102. After the position of the roller bar 412 is adjusted in the adjustment slots 408 and 410, the adjustment nuts 418 can be fastened on the crossbar 416 so that the position of the roller bar 412 in the adjustment slots 408 and 410 is fixed. Thus, when the frames 102 are rotated to the parked position, all of the roller sleeves 414 can engage their corresponding support beams 107. Accordingly, by providing adjustment of the roller bar 412 in the adjustment slots 408 and 410, the brake arm assemblies 400 can compensate for any misalignment between adjacent support beams 107 of a reflector frame assembly 100 so as to ensure that each roller sleeve 414 engages a corresponding support beam 107 in the parked position of the frames 102.

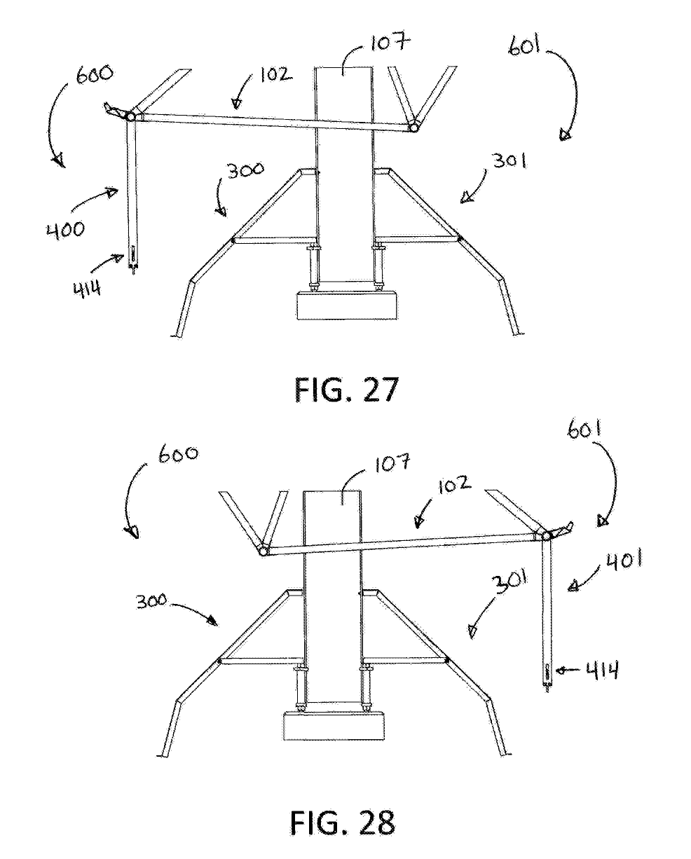

As described above, a brake arm assembly 400 is rotationally attached to one side of the frames 102 and a brake ramp assembly 300 is attached to one side of the support beam 107 to stop the frames 102 from further rotation in the direction 600 after the frames 102 have been placed in the parked position (shown in FIGS. 24-26). Referring to FIGS. 27 and 28, a brake system according to the disclosure may further include a brake ramp assembly 301 and a brake arm assembly 401. The brake ramp assembly 301 may be similar in all or many respects to the brake ramp assembly 300, and may be similarly coupled to the support beam 107 and the ground. The bake arm assembly 401 may be similar in all or many respects to the brake arm assembly 400. The brake arm assembly 401 may be attached to the frames 102 as described in detail above with respect to the brake aim assembly 400. However, as shown by FIGS. 27 and 28, the brake arm assembly 401 is attached to the frames 102 in the gap 109 on the opposite side of the frames 102 relative to the brake arm assembly 400. The brake ramp assembly 301 may be symmetrical to the brake ramp assembly 300 about a vertical axis defining the support beam 107 or a vertical axis that is generally perpendicular to an axis of rotation of the frames 102. The brake ramp assembly 301 and the brake arm assembly 401 function as described above, except that coupling of the brake arm assembly 401 with the brake ramp assembly 301 stops further rotation of the frames 102 in a direction 601 when the roller sleeve 414 of the brake arm assembly 401 engages the support beam 107. Accordingly, the direction 601 is opposite to the direction 600. With the brake system shown in FIGS. 27 and 28, the frames 102 may be stowed or parked in two opposite directions (i.e., generally facing west or generally facing east). Accordingly, the frames 102 can be parked in one of the two directions depending on the direction of the wind to prevent any damage to the frames 102.

The brake ramp 302, the brake arm assembly 400 and/or any components of a brake system according to the disclosure may be constructed from any metal or metal alloys, composite materials, and/or a combination of metals and composite materials. The roller sleeve 414 may be constructed from rubber, foam or other elastically resilient materials so that when the roller sleeve 414 engages the support beam 107, any impact between the roller sleeve 414 and the support beam 107 is dampened by the elastically resilient material. Furthermore, the material from which the roller sleeve 414 is constructed may dampen any vibration of the frames 102 relative to the support beam 107 in the parked position of the frames 102. Further yet, the adjustment screws 416 may include spring and/or dampening sections (not shown) between the roller sleeve 414 and the cross bar 406 to dampen any vibration of the frames 102 relative to the support beam 107 in the parked position of the frames 102.

The above-described brake ramp 302 and the brake arm assembly 400 represent one example of a braking system according to the disclosure. Accordingly, other types of braking systems are possible according to the disclosure. For example, the brake ramp 302 may have a single segment, have more than three segments, and/or have one or more curved segments. The configuration and segmentation of the brake ramp may affect the movement of the roller sleeve on the brake ramp, hence affecting the movement of the frames 102 when rotating in the direction 600 and/or the effort required to rotate the frames 102 in the direction 600. In another example, the brake arm assembly may include only one brake arm or more than two brake arms. The brake arm assembly may have several rollers and/or roller sleeves. In yet another example, the brake ramp may be in the shape of a rail, i.e., a channel, and the brake arm assembly may comprise wheels that engage in the rails of the brake ramp. Thus, any brake ramp and/or brake arm assembly according to the disclosure is possible, where the brake arm assembly at least partially engages the brake ramp during rotation of the frame 102 in the direction 600 to then engage a support beam 107 in the park positions of the frame 102.

The above exemplary brake system is described as having a brake ramp and a brake arm assembly. However, according to other examples, a brake system according to the disclosure may only have a brake arm assembly such that a section of the brake arm assembly engages the support beam at the parked position of the frame without any part of the brake arm assembly engaging a ramp during rotation of the frame from the operational position to the parked position.

A brake system according to the disclosure may be used for any type of frame in a solar power generation system. For example, the brake system may be used in any reflective or photovoltaic system that includes a frame that rotates relative to a support beam or pylon to track the position of the sun. In a concentrated solar tower system, where a plurality of mirrors reflects sunlight onto a central tower, each mirror may be mounted on a frame that is supported by a support beam or pylon. Each frame may include a brake system according to the disclosure. In a photovoltaic system, a plurality of photovoltaic panels may be mounted on a frame that is supported by a support beam or pylon. Each frame may include a brake system according to the disclosure. Thus, a brake system according to the disclosure may be used in any system where a frame rotates relative to one or more frame support members.

Although a particular order of actions is described above, these actions may be performed in other temporal sequences. For example, two or more actions described above may be performed sequentially, concurrently, or simultaneously. Alternatively, two or more actions may be performed in reversed order. Further, one or more actions described above may not be performed at all. The apparatus, methods, and articles of manufacture described herein are not limited in this regard.

While the invention has been described in connection with various aspects, it will be understood that the invention is capable of further modifications. This application is intended to cover any variations, uses or adaptation of the invention following, in general, the principles of the invention, and including such departures from the present disclosure as come within the known and customary practice within the art to which the invention pertains.

What is claimed is:

1. A brake system for a frame of a solar power generation system, the frame being rotatable relative to a frame support to track the position of the sun, the brake system comprising:
a ramp having a first end coupled to the frame support and a second end coupled to the ground; and
a brake arm assembly rotationally coupled to the frame and configured to moveably engage the ramp from an operative position of the frame wherein the frame is rotatable about the support in a rotational direction to a parked position of the frame wherein the brake arm assembly couples to the frame support to prevent the frame from rotating about the frame support in the rotational direction.

2. The brake system of claim 1, the brake arm assembly comprising:
at least one brake arm rotationally coupled to the frame; and
a brake member extending transverse to the at least one brake arm, the brake member configured to moveably engage the ramp from the operative position of the frame to the parked position of the frame.

3. The brake system of claim 1, the brake arm assembly comprising:
at least one brake arm rotationally coupled to the frame; and
a brake member extending transverse to the at least one brake arm, the brake member configured to moveably engage the ramp from the operative position of the frame to the parked position of the frame;
wherein a position of the brake member along the at least one brake arm is adjustable.

4. The brake system of claim 1, the brake arm assembly comprising:
a pair of spaced apart brake arms, each brake arm rotationally coupled to a corresponding frame;
a sleeve rotationally mounted between the brake arms, a position of the sleeve being adjustable along the brake arms;
wherein the sleeve is configured to rotationally engage the ramp from the operative position of the frame to the parked position of the frame; and
wherein the sleeve engages the frame support in the parked position to prevent the frames from rotating about the frame support in the rotational direction.

5. The brake system of claim 1, wherein the brake arm assembly comprises:
a pair of spaced apart brake arms, each brake arm comprising:
an attachment pin configured to engage a node connector of a corresponding frame, and a locking pin configured to lock the attachment pin to the node connector; and
at least one bearing between each attachment pin and a corresponding brake arm such that the brake arm is rotatable relative to the attachment pin;
a roller pin mounted to the brake arms and extending between the brake arms, each end of the roller pin, being movably mounted in an adjustment slot of a corresponding brake arm, a position of each end of the roller pin being fixable with an adjustment fastener; and
a sleeve rotationally mounted on the roller pin, the sleeve configured to rotationally engage the ramp from the operative position of the frame to the parked position of the frame, wherein the sleeve engages the frame support in the parked position to prevent the frames from rotating about the frame support in the rotational direction.

6. The brake system of claim 1, wherein the ramp comprises a plurality of segments, and wherein each segment extends in a different direction than an adjacent segment.

7. A solar power generation system comprising:
a frame support coupled to the ground;
a frame coupled to the frame support and rotatable relative to the frame support to track the position of the sun; and
a brake arm assembly rotatably coupled to the frame and configured to move from an operative position of the frame wherein the frame is rotatable about the support in a rotational direction to a parked position of the frame wherein the brake arm assembly couples to the support to prevent the frame from rotating about the support in the rotational direction.

8. The system of claim 7, further comprising a ramp having a first end coupled to the frame support and a second end coupled to the ground.

9. The system of claim 7, the brake arm assembly comprising at least one brake arm rotationally coupled to the frame, and a brake member extending transverse to the at least one brake arm, the brake member configured to engage the frame support in the parked position of the frame.

10. The system of claim 7, the brake arm assembly comprising:
at least one brake arm rotationally coupled to the frame; and
a brake member extending transverse to the at least one brake arm, the brake member configured to engage the frame support in the parked position of the frame;
wherein a position, of the brake member along the at least one brake arm is adjustable.

11. The system of claim 7, the brake arm assembly comprising:
a pair of spaced apart brake arms, each brake arm rotationally coupled to a corresponding frame;
a pin mounted between the brake arms, a position of the pin being adjustable along the brake arms; and
wherein the pin is configured to engage the frame support in the parked position to prevent the frames from rotating about the frame support in the rotational direction.

12. The system of claim 7., the brake arm assembly comprising:
a pair of spaced apart brake arms, each brake arm comprising:
an attachment pin configured to engage a node connector of a corresponding frame, and a locking pin configured to lock the attachment pin to the node connector; and
at least one bearing between each attachment pin and a corresponding brake arm such that the brake arm is rotatable relative to the attachment pin;
a pin mounted to the brake arms and extending between the brake arms, each end of the roller pin being movably mounted in an adjustment slot of a corresponding brake arm, a position of each end being fixable with an adjustment fastener; and
wherein the pin is configured to engage the frame support in the parked position to prevent the frames from rotating about the frame support in the rotational direction.

13. The system of claim 7, further comprising a ramp having a first end coupled to the frame support and a second end coupled to the ground, wherein the ramp comprises a plurality of segment, wherein each segment extends in a different direction than an adjacent segment, wherein a sleeve rotationally mounted on the brake arm assembly is configured to rotationally engage the ramp from the operative position of the frame to the parked position of the frame, and wherein the sleeve engages the frame support in the parked position to prevent the frames from rotating about the frame support in the rotational direction.

14. A method of manufacturing a brake system for a frame rotatable relative to a frame support, the method comprising:
forming a ramp having a first end configured to be coupled to the support and a second end configured to be coupled to the ground; and
forming a brake arm assembly configured to be rotatably coupled to the frame and configured to moveably engage the ramp from an operative position of the frame wherein the frame is rotatable about the support in a rotational direction to a parked position of the frame wherein the brake arm assembly couples to the support to prevent the frame from rotating about the support in the rotational direction.

15. The method of claim 14, forming the brake arm assembly comprising:
forming at least one brake arm rotationally coupled to the frame; and
forming a brake member extending transverse to the at least one brake arm, the brake member configured to moveably engage the ramp from the operative position of the frame to the parked position of the frame.

16. The method of claim 14, forming the brake arm assembly comprising:
forming at least one brake arm rotationally coupled to the frame; and
forming a brake member extending transverse to the at least one brake arm, the brake member configured to moveably engage the ramp from the operative position of the frame to the parked position of the frame;
wherein a position of the brake member along the at least one brake arm is adjustable.

17. The method of claim 14, forming the brake arm assembly comprising:
forming a pair of spaced apart brake arms, each brake arm rotationally coupled to a corresponding frame;
forming a sleeve rotationally mounted between the brake arms, a position of the sleeve being adjustable along the brake arms;
wherein the sleeve is configured to rotationally engage the ramp from the operative position of the frame to the parked position of the frame; and
wherein the sleeve engages the frame support in the parked position to prevent the frames from rotating about the frame support in the rotational direction.

18. The method of claim 14, forming the brake arm assembly comprises:
forming a pair of spaced apart brake arms, forming each brake arm comprising:
forming an attachment pin configured to engage a node connector of a corresponding frame, and a locking pin configured to lock the attachment pin to the node connector; and
forming at least one bearing between each attachment pin and a corresponding brake arm such that the brake arm is rotatable relative to the attachment pin;
forming a roller pin mounted to the brake arms and extending between the brake arms, each end of the roller pin being movably mounted in an adjustment slot of a corresponding brake arm, a position of each end being fixable with an adjustment fastener; and
forming a sleeve rotationally mounted on the roller pin, the sleeve configured to rotationally engage the ramp from the operative position of the frame to the parked position of the frame, wherein the sleeve engages the frame support in the parked position to prevent the frames from rotating about the frame support in the rotational direction.

19. The method of claim 14, wherein forming the ramp comprises forming a plurality of ramp segments, and wherein each ramp segment extends in a different direction than an adjacent ramp segment.
